(19) United States
(12) Patent Application Publication
(10) Pub. No.: US 2025/0176325 A1
(43) Pub. Date: May 29, 2025

(54) LIGHT-EMITTING DEVICE PACKAGE

(71) Applicant: Samsung Electronics Co., Ltd., Suwon-si (KR)

(72) Inventors: Donghoon LEE, Suwon-si (KR); Chansuk MIN, Suwon-si (KR); Chaeyeon SON, Suwon-si (KR); Jeongrok OH, Suwon-si (KR); Chulsoo YOON, Suwon-si (KR); Sungwoo CHOI, Suwon-si (KR)

(73) Assignee: Samsung Electronics Co., Ltd., Suwon-si (KR)

(21) Appl. No.: 18/953,789

(22) Filed: Nov. 20, 2024

(30) Foreign Application Priority Data
Nov. 23, 2023 (KR) 10-2023-0164854
Apr. 4, 2024 (KR) 10-2024-0046214

(51) Int. Cl. H01L 33/50; H01L 25/16; H01L 33/48; H01L 33/56

(52) U.S. Cl. CPC H10H 20/8513; H10H 20/8506; H10H 20/854; H01L 25/167

(57) ABSTRACT

A light-emitting device package includes a body portion including a first electrode and a second electrode, a semiconductor light-emitting device on the body portion and emitting blue light, and a wavelength conversion portion covering the semiconductor light-emitting device. The wavelength conversion portion includes a transparent encapsulant and a plurality of wavelength conversion materials inside the transparent encapsulant, the plurality of wavelength conversion materials include a green wavelength conversion material, a first red wavelength conversion material, and a second red wavelength conversion material. The first red wavelength conversion material is a Mn⁴⁺ active phosphor. The second red wavelength conversion material is a Eu²⁺ active phosphor including oxygen of more than about 0 wt % and about 2.4 wt % or less. A weight ratio of the second red wavelength conversion material among the plurality of wavelength conversion materials is about 1 wt % to about 6 wt %.

### CROSS-REFERENCE TO RELATED APPLICATIONS

This application is based on and claims priority under 35 U.S.C. § 119 to Korean Patent Application Nos. 10-2023-0164854, filed on Nov. 23, 2023, and 10-2024-0046214, filed on Apr. 4, 2024, in the Korean Intellectual Property Office, the disclosures of which are incorporated by reference herein in their entireties.

### BACKGROUND

The disclosure relates to a light-emitting device package, and more particularly, to a light-emitting device package with excellent light-emitting characteristics.

Light-emitting device packages including semiconductor light-emitting devices are known as next-generation light sources with advantages such as long lifespan, low power consumption, fast response speed, and environmental friendliness compared to light sources of the related art, and are attracting attention as important light sources in various products such as lighting devices and backlights of display devices. Accordingly, light-emitting device packages should have a structure with superior light emission characteristics and few product defects.

### SUMMARY

One or more embodiments of the disclosure can provide a light-emitting device package with improved light-emitting efficiency by adjusting a weight ratio of a wavelength conversion material.

The problems to be solved by the disclosure are not limited to the above-mentioned problems, and other problems not mentioned will be clearly understood by those skilled in the art from the following description.

According to an aspect of the disclosure, there is provided a light-emitting device package including a body portion including a first electrode and a second electrode, a semiconductor light-emitting device on the body portion and emitting blue light, and a wavelength conversion portion covering the semiconductor light-emitting device, wherein the wavelength conversion portion includes a transparent encapsulant and a plurality of wavelength conversion materials disposed inside the transparent encapsulant, the plurality of wavelength conversion materials include a green wavelength conversion material, a first red wavelength conversion material, and a second red wavelength conversion material, the first red wavelength conversion material is a Mn⁴⁺ active phosphor, the second red wavelength conversion material is a Eu²⁺ active phosphor including oxygen of more than about 0 wt % and about 2.4 wt % or less, and a weight ratio of the second red wavelength conversion material among the plurality of wavelength conversion materials is about 1 wt % to about 6 wt %.

According to another aspect of the disclosure, there is provided a light-emitting device package including a plurality of wavelength conversion materials configured to emit white light with a color rendering index (CRI) of 90 or more and an R9 value of 50 or more from blue light having a peak wavelength of about 447 nm to about 457 nm emitted from a semiconductor light-emitting device, wherein the plurality of wavelength conversion materials include a Y₃(Al,Ga)₅O₁₂:Ce³⁺ phosphor as a green wavelength conversion material, a K₂SiF₆:Mn⁴⁺ phosphor as a first red wavelength conversion material, and a (Sr,Ca)AlSi(ON)₃:Eu²⁺ phosphor as a second red wavelength conversion material, and a weight ratio of the second red wavelength conversion material among the plurality of wavelength conversion materials is about 1 wt % to about 6 wt %.

According to another aspect of the disclosure, there is provided a light-emitting device package including a plurality of wavelength conversion materials configured to emit white light with a CRI of 90 or more and an R9 value of 50 or more from blue light having a peak wavelength of about 447 nm to about 457 nm emitted from a semiconductor light-emitting device, wherein the plurality of wavelength conversion materials include a Y₃(Al,Ga)₅O₁₂:Ce³⁺ phosphor as a green wavelength conversion material, a K₂SiF₆:Mn⁴⁺ phosphor as a first red wavelength conversion material, and a (Sr,Ca)AlSi(ON)₃:Eu²⁺ phosphor stateing oxygen of more than about 0 wt % and about 2.4 wt % or less as a second red wavelength conversion material.

### BRIEF DESCRIPTION OF DRAWINGS

Embodiments will be more clearly understood from the following detailed description taken in conjunction with the accompanying drawings in which:

FIG. 1 is a cross-sectional view showing a main configuration of a light-emitting device package according to one or more embodiments;

FIG. 2 is a cross-sectional views showing a configuration of a light-emitting device package according to one or more embodiments;

FIG. 3 is a cross-sectional views showing a configuration of a light-emitting device package according to one or more embodiments;

FIG. 4 is a graph showing the relationship between visibility and speed of light;

FIG. 5 is a schematic cross-sectional view of a white light source module including a light-emitting device package according to one or more embodiments;

FIG. 6 is a schematic cross-sectional view of a white light source module including a light-emitting device package according to one or more embodiments;

FIG. 7A is a schematic cross-sectional view of a white light source module that is employable in a lighting device as a light-emitting device package according to one or more embodiments;

FIG. 7B is a schematic cross-sectional view of a white light source module that is employable in a lighting device as a light-emitting device package according to one or more embodiments;

FIG. 8 is a Commission Internationale de l′Éclairage (CIE) chromatic diagram showing a full radiator spectrum that may be used in a light-emitting device package according to one or more embodiments;

FIG. 9 is a schematic perspective view of a backlight unit including a light-emitting device package according to one or more embodiments;

FIG. 10 is a diagram showing a direct backlight unit including a light-emitting device package according to one or more embodiments;

FIG. 11 is a diagram showing a backlight unit including a light-emitting device package according to one or more embodiments;

FIG. 12 is a diagram for explaining a direct backlight unit including a light-emitting device package according to one or more embodiments;

FIG. 13 is a diagram for explaining a direct backlight unit including a light-emitting device package according to one or more embodiments;

FIG. 14 is a diagram for explaining backlight units including light-emitting device packages according to one or more embodiments;

FIG. 15 is a diagram for explaining backlight units including light-emitting device packages according to one or more embodiments;

FIG. 16 is a diagram for explaining backlight units including light-emitting device packages according to one or more embodiments;

FIG. 17 is a schematic exploded perspective view of a display device including a light-emitting device package according to one or more embodiments;

FIG. 18 is a perspective view schematically showing a flat lighting device including a light-emitting device package according to one or more embodiments;

FIG. 19 is an exploded perspective view schematically showing a lighting device including light-emitting device packages according to one or more embodiments;

FIG. 20 is an exploded perspective view schematically showing a lighting device including a light-emitting device package according to one or more embodiments;

FIG. 21 is an exploded perspective view schematically showing a bar-type lighting device including a light-emitting device package according to one or more embodiments;

FIG. 22 is a schematic diagram illustrating an indoor lighting control network system including a light-emitting device package according to one or more embodiments;

FIG. 23 is a schematic diagram illustrating a network system including a light-emitting device package according to one or more embodiments;

FIG. 24 is a block diagram for explaining a communication operation between a smart engine of a lighting instrument including a light-emitting device package and a mobile device, according to one or more embodiments; and

FIG. 25 is a conceptual diagram schematically showing a smart lighting system including a light-emitting device package according to one or more embodiments.

### DETAILED DESCRIPTION OF EMBODIMENTS

Hereinafter, embodiments of the disclosure will be described in detail with reference to the accompanying drawings.

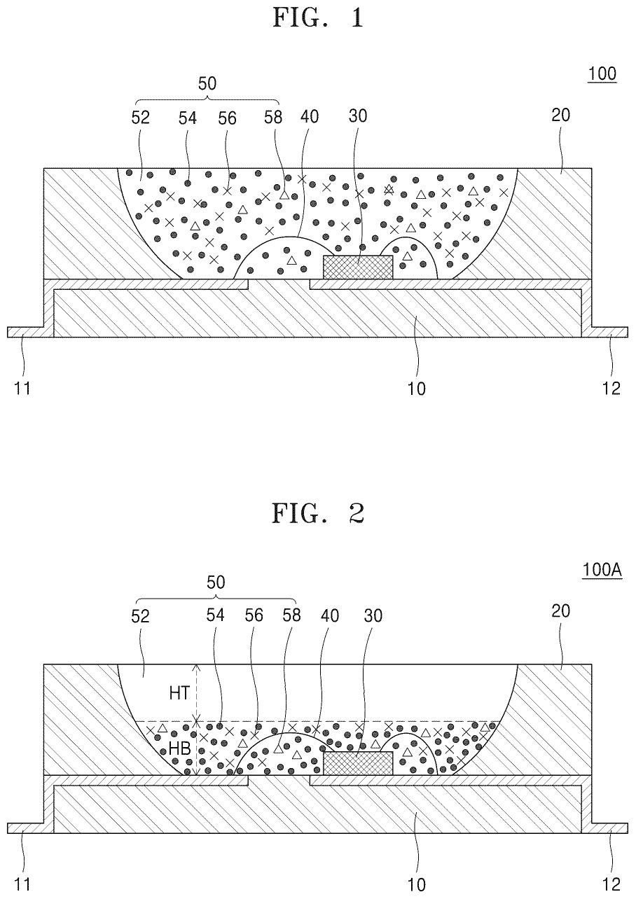

FIG. 1 is a cross-sectional view showing a main configuration of a light-emitting device package 100 according to one or more embodiments.

Referring to FIG. 1, the light-emitting device package 100 includes a body portion 10, a first electrode 11 and a second electrode 12 disposed on the body portion 10, a side wall portion 20 disposed on the body portion 10 and including a cavity, a semiconductor light-emitting device 30 disposed in the cavity, a conductive wire 40 connecting the first electrode 11 and the second electrode 12 to the semiconductor light-emitting device 30, and a wavelength conversion portion 50 that fills the cavity and covers the semiconductor light-emitting device 30.

The body portion 10 and the side wall portion 20 may each include a silicone material, a synthetic resin material, or a metal material. The semiconductor light-emitting device 30 may be disposed on the body portion 10. In addition, the side wall portion 20 may include the cavity, and a bottom surface of the cavity may serve as a mounting surface of the semiconductor light-emitting device 30. The side wall portion 20 is formed to have an inclined surface around the semiconductor light-emitting device 30 to increase light extraction efficiency.

The first electrode 11 and the second electrode 12 are electrically separated from each other and provide power to the semiconductor light-emitting device 30. In some embodiments, the first electrode 11 and the second electrode 12 may increase light extraction efficiency by reflecting light generated from the semiconductor light-emitting device 30, and may serve to discharge heat generated from the semiconductor light-emitting device 30 to the outside.

The semiconductor light-emitting device 30 may be disposed on the body portion 10, or on the first electrode 11 or the second electrode 12. It is shown that the semiconductor light-emitting device 30 is disposed on the second electrode 12, but the disclosure is not limited thereto.

The conductive wire 40 may electrically connect the first electrode 11 and the second electrode 12 to the semiconductor light-emitting device 30. The first electrode 11 and the second electrode 12 may be electrically connected to the semiconductor light-emitting device 30 by using either a flip chip method or a die bonding method.

The wavelength conversion portion 50 may fill the inside of the cavity so as to cover the semiconductor light-emitting device 30 and the conductive wire 40 on the body portion 10. The wavelength conversion portion 50 may include a transparent encapsulant 52 and a plurality of wavelength conversion materials 54, 56, and 58 disposed inside the transparent encapsulant 52.

The plurality of wavelength conversion materials 54, 56, and 58 may include a green wavelength conversion material 54, a first red wavelength conversion material 56, and a second red wavelength conversion material 58. Here, the green wavelength conversion material 54 refers to a green phosphor, and each of the first red wavelength conversion material 56 and the second red wavelength conversion material 58 refers to a red phosphor. In addition, the first red wavelength conversion material 56 refers to a first red phosphor, and the second red wavelength conversion material 58 refers to a second red phosphor.

In one or more embodiments, the semiconductor light-emitting device 30 may be a blue light-emitting device capable of emitting blue light with a peak wavelength of about 447 nm to about 457 nm such that the light-emitting device package 100 may emit white light. In addition, the wavelength conversion portion 50 may combine a green phosphor and a red phosphor to implement a color temperature and a color rendering index (CRI) of white light from blue light emitted from the semiconductor light-emitting device 30.

The transparent encapsulant 52 may constitute the exterior of the wavelength conversion portion 50, and the plurality of wavelength conversion materials 54, 56, and 58 may be dispersed and distributed inside the transparent encapsulant 52. In some embodiments, the plurality of wavelength conversion materials 54, 56, and 58 may be uniformly dispersed and distributed throughout the transparent encapsulant 52.

The transparent encapsulant 52 may be resin. In some embodiments, the transparent encapsulant 52 may include silicone having a refractive index of about 1.41 to about 1.54. When a refractive index of a material of the transparent encapsulant 52 is less than 1.41, because gas transmittance is low, reliability may be weakened, and when the refractive index is greater than 1.54, resistance to discoloration and cracks due to phenyl groups may be vulnerable.

The green wavelength conversion material 54 may include a Ce³⁺ active phosphor. In some embodiments, the green wavelength conversion material 54 may be a Y₃(Al,Ga)₅O₁₂:Ce³⁺ phosphor (hereinafter referred to as a GaYAG phosphor). A weight ratio of the green wavelength conversion material 54 among the plurality of wavelength conversion materials 54, 56, and 58 may be expressed as a numerical value excluding a weight ratio of each of the first red wavelength conversion material 56 and the second red wavelength conversion material 58 among the plurality of wavelength conversion materials 54, 56, and 58. For example, the weight ratio of the green wavelength conversion material 54 among the plurality of wavelength conversion materials 54, 56, and 58 may be about 38 wt % to about 64 wt %.

The first red wavelength conversion material 56 may include a Mn⁴⁺ active phosphor. In some embodiments, the first red wavelength conversion material 56 may be a K₂SiF₆:Mn⁴⁺ phosphor (hereinafter referred to as a KSF phosphor). The weight ratio of the first red wavelength conversion material 56 among the plurality of wavelength conversion materials 54, 56, and 58 varies depending on color temperature, but may be, for example, about 32 wt % to about 56 wt %. When the weight ratio of the first red wavelength conversion material 56 is less than 32 wt %, the speed of light may increase but the CRI may decrease, and when the weight ratio is greater than 56 wt %, the color rendering may increase but the speed of light may decrease.

In one or more embodiments, the second red wavelength conversion material 58 may include a Eu²⁺ active phosphor. In some embodiments, the first red wavelength conversion material 56 may be a (Sr,Ca)AlSi(ON)₃:Eu²⁺ phosphor (hereinafter referred to as an SCASN phosphor). Here, the first red wavelength conversion material 56 may include oxygen of more than about 0 wt % and about 2.4 wt % or less (with respect to the ELTRA's ON analyzer). When oxygen in the first red wavelength conversion material 56 is greater than 2.4 wt %, because a full width at half maximum (FWHM) is widened, the first red wavelength conversion material 56 may be unsuitable for use.

In addition, the weight ratio of the second red wavelength conversion material 58 among the plurality of wavelength conversion materials 54, 56, and 58 varies depending on the color temperature, but may be, for example, about 1 wt % to about 6 wt %. When the weight ratio of the second red wavelength conversion material 58 is less than 1 wt %, the CRI may increase but the speed of light may decrease, and when the weight ratio is greater than 6 wt %, the speed of light may increase but the color rendering may decrease. For example, see Table 1 below for specific values under the color temperature of 5000 K.

TABLE 1

| green phosphor and | second red | speed of | | |
|---|---|---|---|---|
| first red phosphor | phosphor | light | CRI | R9 |
| 100.0 wt % | — | 100.0% | 92.0 | 92.4 |
| 99.0 wt % | 1.0 wt % | 100.6% | 94.1 | 97.5 |
| 98.0 wt % | 2.0 wt % | 101.2% | 93.0 | 82.2 |
| 96.0 wt % | 4.0 wt % | 101.8% | 91.1 | 67.0 |
| 93.0 wt % | 7.0 wt % | 102.5% | 89.0 | 52.0 |

Therefore, in order to implement the characteristics of a high speed of light (exceeding 100%), a high CRI (90 or more), and a high R9 value (50 or more), the green wavelength conversion material 54, the first red wavelength conversion material 56, and the second red wavelength conversion material 58 need to satisfy the respective weight ratio conditions. See Table 2 below for specific values in color temperature ranges (2600 K to 6600 K).

TABLE 2

| color | | | Second red |
|---|---|---|---|
| temperature | green phosphor | first red phosphor | phosphor |
| 2600 K to | 38 wt % to 40 wt % | 54 wt % to 56 wt % | 4 wt % to |
| 2800 K | | | 6 wt % |
| 2900 K to | 40 wt % to 42 wt % | 53 wt % to 55 wt % | 4 wt % to |
| 3100 K | | | 6 wt % |
| 3400 K to | 47 wt % to 49 wt % | 47 wt % to 49 wt % | 4 wt % to |
| 3600 K | | | 6 wt % |
| 3900 K to | 49 wt % to 51 wt % | 46 wt % to 48 wt % | 2 wt % to |
| 4100 K | | | 4 wt % |
| 4900 K to | 58 wt % to 60 wt % | 37 wt % to 39 wt % | 2 wt % to |
| 5100 K | | | 4 wt % |
| 5600 K to | 61 wt % to 63 wt % | 34 wt % to 36 wt % | 1 wt % to |
| 5800 K | | | 3 wt % |
| 6400 K to | 63 wt % to 65 wt % | 32 wt % to 34 wt % | 2 wt % to |
| 6600 K | | | 4 wt % |

In addition, the weight ratio of the second red wavelength conversion material 58 among the total weight ratio of the first red wavelength conversion material 56 and the second red wavelength conversion material 58 may be about 5 wt % to about 10 wt %. See Table 3 below for specific values at color temperature ranges (2700 K to 6500 K).

TABLE 3

| color temperature | first red phosphor | second red phosphor |
|---|---|---|
| 2700 K | 90 wt % to 92 wt % | 8 wt % to 10 wt % |
| 3000 K | 91 wt % to 93 wt % | 7 wt % to 9 wt % |
| 3500 K | 90 wt % to 92 wt % | 8 wt % to 10 wt % |
| 4000 K | 92 wt % to 94 wt % | 6 wt % to 8 wt % |
| 5000 K | 92 wt % to 94 wt % | 6 wt % to 8 wt % |
| 5700 K | 93 wt % to 95 wt % | 5 wt % to 7 wt % |
| 6500 K | 92 wt % to 94 wt % | 6 wt % to 8 wt % |

Through the second red wavelength conversion material 58 that satisfies these conditions, in one or more embodiments, the light-emitting device package 100 may emit red light having a peak wavelength of about 595 nm to about 615 nm and an FWHM of 78 nm or less.

The light-emitting device package 100 including the semiconductor light-emitting device 30 is known as a next-generation light source with advantages such as long lifespan, low power consumption, fast response speed, and environmental friendliness compared to the light source of the related art, and are attracting attention as important light sources in various products such as lighting devices and backlights of display devices. Accordingly, the light-emitting device package 100 may have a structure with superior light emission characteristics and low product defects.

In order to satisfy these requirements, the light-emitting device package 100 that emits white light, which is generally used in a lighting device, may have a high speed of light and a high CRI. In order for the light-emitting device package 100 to have a high CRI, a KSF phosphor with a narrow FWHM may be used as a red wavelength conversion material.

The inventors of the disclosure have studied the light-emitting device package 100 that may maximize the speed of light while implementing a high CRI by using a specific amount of the KSF phosphor. In order to apply the KSF phosphor with the narrow FWHM to a lighting device, it is necessary to secure an appropriate level of reliability.

Because, in order to satisfy the long life characteristics of the lighting device, it is an important assignment to use only an appropriate amount of KSF phosphor, which is somewhat less reliable. In addition, due to the characteristics of the lighting device, it is an essential requirement to improve reliability while maintaining a high CRI and a high speed of light. In other words, a method of securing a lifespan similar to that of a light-emitting device package to which a KSF phosphor is not applied is needed.

As the method, the inventors of the disclosure have proposed a method of including a SCASN phosphor including oxygen at a certain weight ratio, as the second red wavelength conversion material 58, in the light-emitting device package 100.

Ultimately, the light-emitting device package 100 according to one or more embodiments may adjust the weight ratio of each of the plurality of wavelength conversion materials 54, 56, and 58 included in the wavelength conversion portion 50 covering the semiconductor light-emitting device 30, and thus, the light emission efficiency is improved.

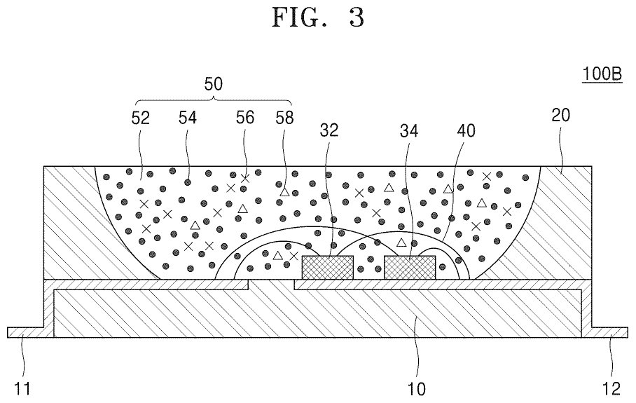

FIGS. 2 and 3 are cross-sectional views showing main configurations of light-emitting device packages 100A and 100B according to one or more embodiments.

Most of components constituting the light-emitting device packages 100A and 100B described below and materials of the components are substantially the same as or similar to those previously described with reference to FIG. 1. Therefore, for convenience of explanation, differences from the light-emitting device package 100 described above are mainly described.

Referring to FIG. 2, the light-emitting device package 100A includes the body portion 10, the first electrode 11 and the second electrode 12 disposed on the body portion 10, the side wall portion 20 disposed on the body portion 10 and including a cavity, the semiconductor light-emitting device 30 disposed in the cavity, the conductive wire 40 connecting the first electrode 11 and the second electrode 12 to the semiconductor light-emitting device 30, and the wavelength conversion portion 50 that fills the cavity and covers the semiconductor light-emitting device 30.

In one or more embodiments, the wavelength conversion portion 50 may include the transparent encapsulant 52 and the plurality of wavelength conversion materials 54, 56, and 58 disposed inside the transparent encapsulant 52. In some embodiments, when an upper vertical length HT and a lower vertical length HB of the transparent encapsulant 52 are substantially the same, the plurality of wavelength conversion materials 54, 56, and 58 may be distributed and arranged only in a lower portion of the transparent encapsulant 52.

In other words, the transparent encapsulant 52 may have a first section closest to the body portion (in lower vertical length HB) and a second section furthest from the body portion (in vertical length HT). HB and HT may each comprise half of the thickness of transparent encapsulant 52, or some other percentage. In some embodiments, only the first section or the second section has wavelength conversion materials 54, 56, and 58 dispersed therein. In some embodiments, both the first section and the second section have wavelength conversion materials 54, 56, and 58 dispersed therein.

Although not bound by a specific theory, due to the weight of the plurality of wavelength conversion materials 54, 56, and 58 and/or the viscosity of the transparent encapsulant 52, the plurality of wavelength conversion materials 54, 56, and 58 may be disposed in the lower portion (first section) of the transparent encapsulant 52, that is, around the semiconductor light-emitting device 30, to have a higher distribution density.

Referring to FIG. 3, the light-emitting device package 100B includes the body portion 10, the first electrode 11 and the second electrode 12 disposed on the body portion 10, the side wall portion 20 disposed on the body portion 10 and including a cavity, a first semiconductor light-emitting device 32 and a second semiconductor light-emitting device 34 disposed in the cavity, the conductive wire 40 connecting the first electrode 11 and the second electrode 12 to the first semiconductor light-emitting device 32 and the second semiconductor light-emitting device 34, and the wavelength conversion portion 50 that fills the cavity and covers the first semiconductor light-emitting device 32 and the second semiconductor light-emitting device 34.

In one or more embodiments, the first semiconductor light-emitting device 32 and the second semiconductor light-emitting device 34 may be disposed on the body portion 10 or on the first electrode 11 or the second electrode 12. It is shown that the first semiconductor light-emitting device 32 and the second semiconductor light-emitting device 34 are disposed on the second electrode 12, but the disclosure is not limited thereto.

In some embodiments, the first semiconductor light-emitting device 32 and the second semiconductor light-emitting device 34 may be the same type of semiconductor light-emitting devices, and in some embodiments, the first semiconductor light-emitting device 32 and the second semiconductor light-emitting device 34 may be different types of semiconductor light-emitting devices.

For convenience of explanation, it is shown that the number of the first semiconductor light-emitting device 32 and the second semiconductor light-emitting device 34 is two, but the number of the first semiconductor light-emitting device 32 and the second semiconductor light-emitting device 34 is not limited thereto. For example, three or more semiconductor light-emitting devices may be included in the light-emitting device package 100B.

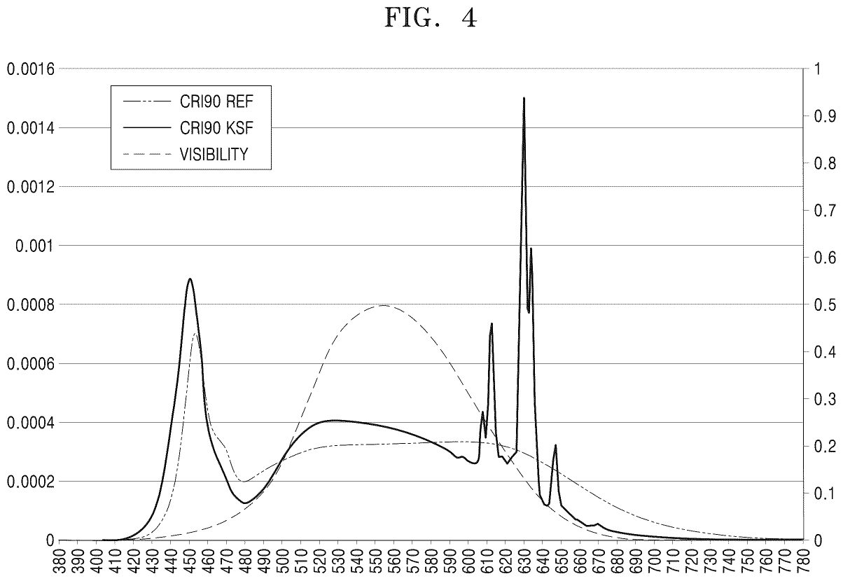

FIG. 4 is a graph showing the relationship between visibility and speed of light.

Referring to FIG. 4, in the graph, the horizontal axis represents the wavelength (nanometer unit), and the vertical axis represents the intensity (arbitrary unit).

In the graph, a visibility curve has the maximum intensity at a wavelength of 555 nm, and the intensity decreases toward left and right wavelength regions by using the maximum intensity as a baseline. When phosphors used in a light-emitting device package have the same or similar efficiencies, the left and right wavelength regions (particularly, the right wavelength region) may be relatively less important regions.

Therefore, in a light-emitting device package using a KSF phosphor as a red wavelength conversion material, a spectrum in the right wavelength region, which does not significantly contribute to a speed of light, may be considered to be relatively less important. Therefore, compared to a control group (CRI90 REF) with the same CRI, the speed of light of an experimental group (CRI90 KSF), which has the maximum intensity at a wavelength of 555 nm, may be a more important factor.

That is, according to one or more embodiments, the light emission efficiency is improved in the light-emitting device package (100, see FIG. 1) using the KSF phosphor as the first red wavelength conversion material (56, see FIG. 1).

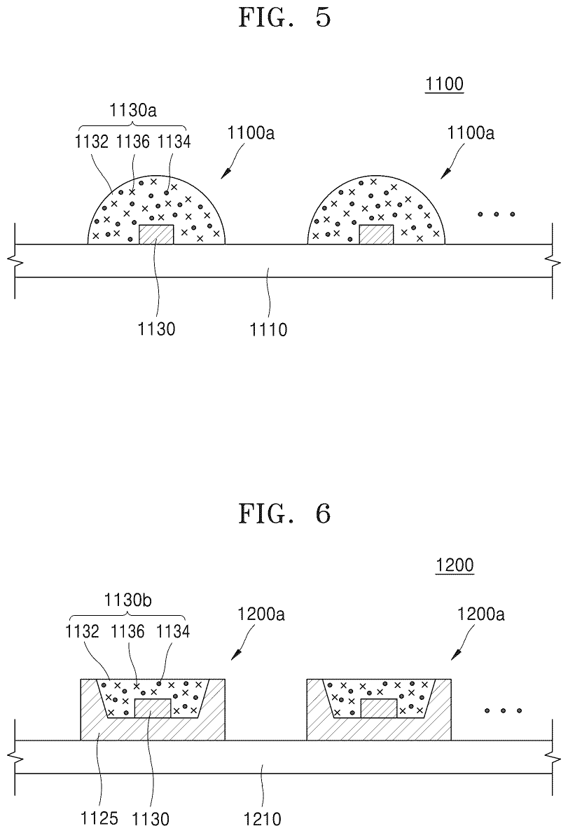

FIGS. 5 and 6 are schematic cross-sectional views of white light source modules including light-emitting device packages 1100a and 1200a respectively according to one or more embodiments.

Referring to FIG. 5, a backlight light source module 1100 may include a circuit board 1110 and an arrangement of a plurality of light-emitting device packages 1100a mounted on the circuit board 1110.

A conductive pattern connected to the light-emitting device package 1100a may be formed on an upper surface of the circuit board 1110. The light-emitting device package 1100a may be any one of the light-emitting device packages 100, 100A, and 100B according to one or more embodiments described above.

Each of the light-emitting device packages 1100a may have a structure in which a semiconductor light-emitting device 1130 that emits blue light is directly mounted on the circuit board 1110 by using a chip on board (COB) method. Each of the light-emitting device packages 1100a includes a wavelength conversion portion 1130a in a hemispherical shape with a lens function to exhibit a wide beam angle. This wide beam angle may contribute to reducing a thickness or a width of a display.

Referring to FIG. 6, a backlight light source module 1200 may include a circuit board 1210 and an arrangement of a plurality of light-emitting device packages 1200a mounted on the circuit board 1210.

Each of the light-emitting device packages 1200a may include a semiconductor light-emitting device 1130 that emits blue light mounted within a reflective cup of a package body 1125 and a wavelength conversion portion 1130b that encapsulates the semiconductor light-emitting device 1130. The light-emitting device package 1200a may be any one of the light-emitting device packages 100, 100A, and 100B according to one or more embodiments described above.

The wavelength conversion portions 1130a and 1130b may each include wavelength conversion materials 1132, 1134, and 1136 such as phosphors and/or quantum dots, as needed. Details about the wavelength conversion material are as described above.

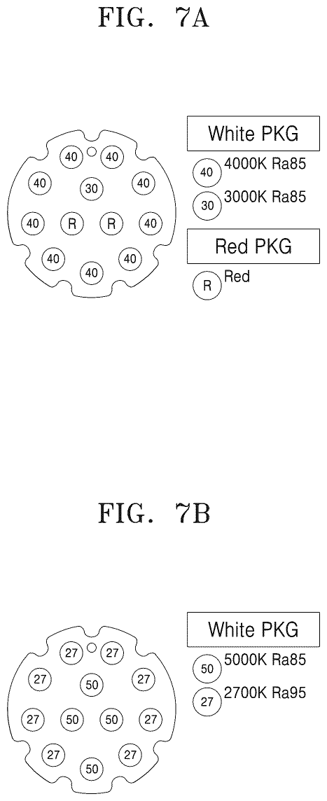

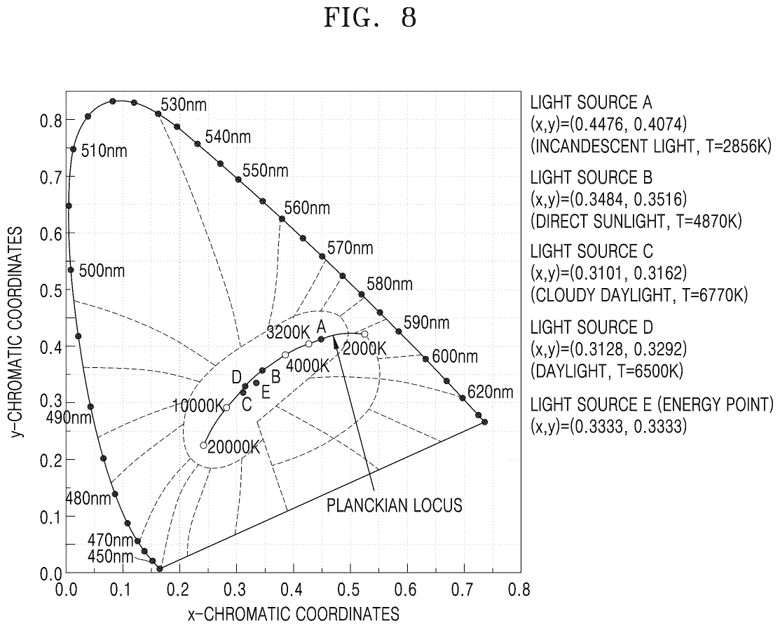

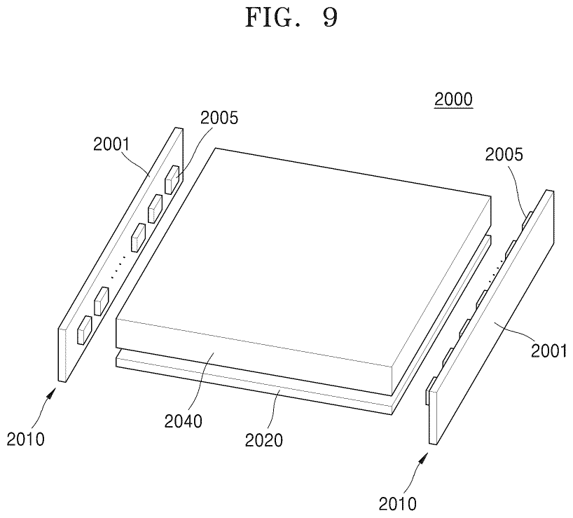

FIG. 7A is a schematic cross-sectional view of a white light source module that is employable in a lighting device as a light-emitting device package according to one or more embodiments. FIG. 7B is a schematic cross-sectional view of a white light source module that is employable in a lighting device as a light-emitting device package according to one or more embodiments. FIG. 8 is a CIE chromatic diagram showing a full radiator spectrum that may be used in a light-emitting device package according to one or more embodiments.

Specifically, each of light source modules shown in FIGS. 7A and 7B may include a plurality of light-emitting device packages mounted on a circuit board. The plurality of light-emitting device packages may be any one of the light-emitting device packages 100, 100A, and 100B according to one or more embodiments described above.

The plurality of light-emitting device packages mounted on one light source module may be the same type of packages that generates light of the same wavelength, but as in the embodiment, may be different types of packages that generate light of different wavelengths.

Referring to FIG. 7A, in some embodiments, the white light source module may be configured by combining a white light-emitting device package and a red light-emitting device package with color temperatures of about 4000 K and about 3000 K. The white light source module may provide white light with a color temperature adjustable in the range of about 3000 K to about 4000 K and a CRI Ra (average) in the range of about 85 to about 100.

Referring to FIG. 7B, in some embodiments, the white light source module may be configured as only a white light-emitting device package, but some packages may have white light of different color temperatures. For example, the white light source module may combine a white light-emitting device package with a color temperature of 2700 K and a white light-emitting device package with a color temperature of 5000 K to provide white light with a color temperature adjustable in the range of about 2700 K to about 5000 K and the CRI Ra in the range of about 85 to about 99. Here, the number of light-emitting device packages for each color temperature may mainly vary depending on a basic color temperature setting value.

In a single light-emitting device package, the desired color of light is determined according to a wavelength of a light-emitting diode (LED) chip, which is a light-emitting device, and types and a mixing ratio of phosphors. In the case of white light, a color temperature and a CRI may be adjusted.

For example, when a semiconductor light-emitting device emits blue light, a light-emitting device package including at least one of yellow, green, and red phosphors may emit white light with various color temperatures according to the mixing ratio of the phosphors. In contrast, a light-emitting device package that applies green or red phosphor to a semiconductor light-emitting device may emit green or red light.

In heterogeneous light-emitting device packages, the color temperature and the CRI of white light may be adjusted by combining a light-emitting device package that emits white light and a light-emitting device package that emits green or red light. In addition, the white light source module may be configured to include at least one of light-emitting device packages that emit purple, blue, green, red, or infrared light.

In this case, the lighting device may adjust the CRI to a level of sunlight, also generate a variety of white light with a color temperature ranging from 1500 K to 20000 K, and as needed, generate visible light or infrared light in purple, blue, green, red, and orange to adjust a lighting color to suit a surrounding atmosphere or mood. In addition, the lighting device may generate light of a special wavelength that may promote plant growth.

Referring to FIG. 8, white light produced by combining a semiconductor light-emitting device of blue light with yellow, green, and/or red phosphors may have two or more peak wavelengths, and (x, y) coordinates of a CIE coordinate system may be located within a line segment region connecting A(0.4476, 0.4074), B(0.3484, 0.3516), C(0.3101, 0.3162), D(0.3128, 0.3292), and E(0.3333, 0.3333). Alternatively, white light may be located in a region surrounded by a line segment and a blackbody radiation spectrum. The color temperature of white light is between about 1500 K and about 20000 K.

The white light near point E(0.3333, 0.3333) on a lower portion of blackbody radiation spectrum (Planckian locus) may be used as an illumination light source in a region that a person may have a clearer feeling or a fresher feeling to the naked eye in a state in which light of a yellow component is relatively weakened. Therefore, lighting products using the white light near point E(0.3333, 0.3333) on the lower portion of blackbody radiation spectrum are effective as commercial lighting for selling groceries and clothing.

Meanwhile, various materials such as phosphors and/or quantum dots may be used as materials for converting a wavelength of light emitted from a semiconductor light-emitting device.

The phosphor may have the following composition formula and color.

Oxides: yellow and green Y₃Al₅O₁₂:Ce, Tb₃A₁₅O₁₂:Ce, Lu₃A₁₅O₁₂:Ce

Silicates: yellow and green (Ba,Sr)₂SiO₄:Eu, yellow and orange (Ba,Sr)₃SiO₅:Ce

Nitrides: green —SiAlON:Eu, yellow La₃Si₆N₁₁:Ce, orange —SiAlON:Eu, red —CaAlSiN₃:Eu, Sr₂Si₅N₈:Eu, SrSiAl₄N₇:Eu, SrLiAl₃N₄:Eu, Ln₄₋ₓ(Eu_{z}M_{1-z})ₓSi_{12-y}AlyO_{3+x+y}N_{18-x-y}(0.5<x=3, 0<z<0.3, 0<y=4) (provided that Ln is at least one element selected from the group consisting of group IIIa elements and rare earth elements, and M is at least one element selected from the group consisting of Ca, Ba, Sr and Mg)

Fluorides: KSF red K₂SiF₆:Mn⁴⁺, K₂TiF₆:Mn⁴⁺, NaYF₄:Mn⁴⁺, NaGdF₄:Mn⁴⁺, K₃SiF₇:Mn⁴⁺

The composition of the phosphor needs to basically comply with stoichiometry, and each of elements may be substituted with other elements within each group on the periodic table. For example, Sr may be substituted with alkaline earth (II) group Ba, Ca, Mg, etc., and Y may be substituted with lanthanides Tb, Lu, Sc, Gd, etc. In addition, Eu, which is an activator, may be substituted with Ce, Tb, Pr, Er, Yb, etc., according to the desired energy level, and an additional inactivator may be applied to the activator alone or to modify properties.

In particular, the fluorite-based red phosphor may be coated with a fluoride that does not contain Mn to improve reliability at high temperature/high humidity, or may further include an organic coating on a surface of the phosphor or a surface of fluoride coating that does not contain Mn. Unlike other phosphors, the fluorite-based red phosphor may implement a narrow FWHM of 40 nm or less, and may be used in a high-resolution display such as an ultra high definition (UHD) display.

FIG. 9 is a schematic perspective view of a backlight unit 2000 including a light-emitting device package according to one or more embodiments.

Referring to FIG. 9, the backlight unit 2000 may include a light guide plate 2040 and a light source module 2010 provided on both sides of the light guide plate 2040. In addition, the backlight unit 2000 may include a reflector 2020 disposed on a lower portion of the light guide plate 2040. The backlight unit 2000 of the embodiment may be an edge backlight unit.

The light source module 2010 may be provided only on one side of the light guide plate 2040, or may be additionally provided on the other side. The light source module 2010 may include a printed circuit board 2001 and a plurality of light sources 2005 mounted on the printed circuit board 2001. The plurality of light sources 2005 may be any one of the light-emitting device packages 100, 100A, and 100B according to one or more embodiments described above.

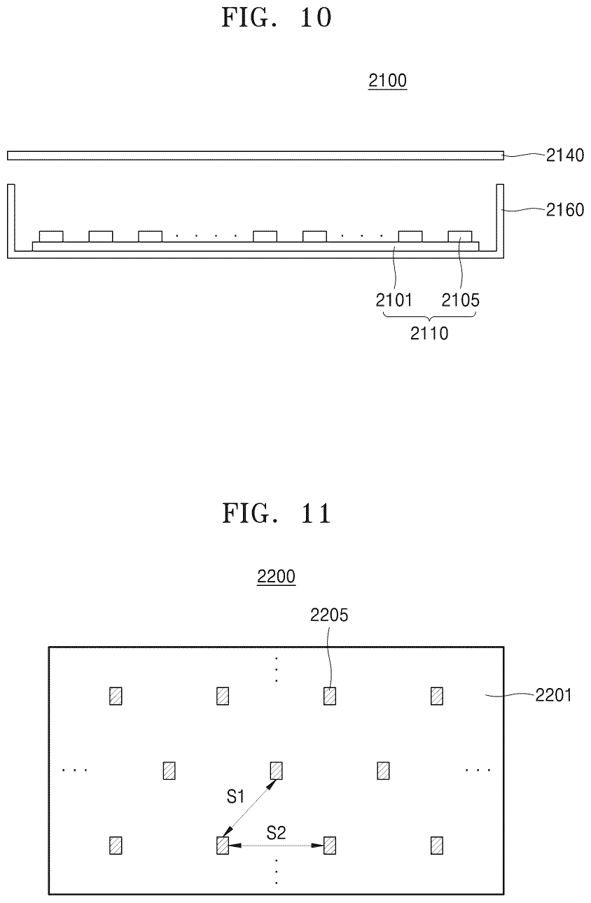

FIG. 10 is a diagram showing a direct backlight unit 2100 including a light-emitting device package according to one or more embodiments.

Referring to FIG. 10, the backlight unit 2100 may include a light diffusion plate 2140 and light source modules 2110 arranged on a lower portion of the light diffusion plate 2140. In addition, the backlight unit 2100 may include a bottom case 2160 disposed on the lower portion of the light diffusion plate 2140 and accommodating the light source modules 2110. The backlight unit 2100 of the embodiment may be the direct backlight unit.

The light source module 2110 may include a printed circuit board 2101 and a plurality of light sources 2105 mounted on the printed circuit board 2101. The plurality of light sources 2105 may be any one of the light-emitting device packages 100, 100A, and 100B according to one or more embodiments described above.

FIG. 11 is a diagram showing a backlight unit 2200 including a light-emitting device package according to one or more embodiments.

Referring to FIG. 11, one or more examples in which a plurality of light sources 2205 are arranged in the direct backlight unit 2200 is shown. The plurality of light sources 2205 may be any one of the light-emitting device packages 100, 100A, and 100B according to one or more embodiments described above.

The direct backlight unit 2200 according to the embodiment includes the plurality of light sources 2205 arranged on a substrate 2201. An arrangement structure of the plurality of light sources 2205 is a matrix structure arranged in rows and columns, and each row and column has a zigzag shape.

In other words, the arrangement structure is a structure in which a second matrix of the same type is disposed inside a first matrix in which the plurality of light sources 2205 are arranged in rows and columns in a straight line, and may be understood that each of the light sources 2205 of the second matrix is located inside a square formed by the four adjacent light sources 2205 included in the first matrix.

However, in order for the direct backlight unit 2200 to further improve luminance uniformity and light efficiency, the first matrix and second matrix may have different arrangement structures and distances, when necessary. In addition, in addition to the arrangement method of the plurality of light sources 2205, distances S1 and S2 between adjacent light sources may be optimized to ensure luminance uniformity.

As described above, the rows and columns including the plurality of light sources 2205 are arranged in a zigzag manner rather than in a straight line, and thus, the number of light sources 2205 may be reduced by about 15% to about 25% with respect to the same light emission region.

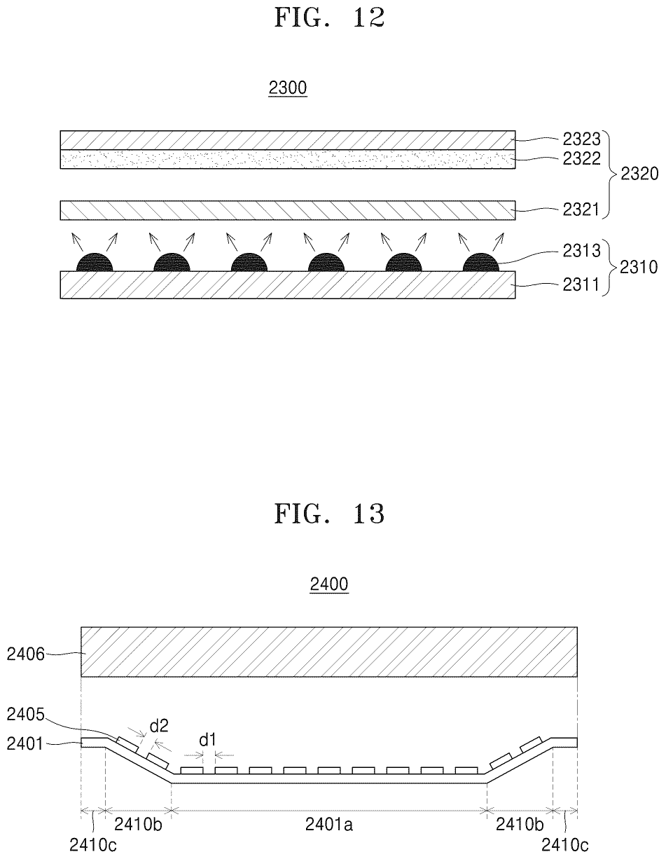

FIG. 12 is a diagram for explaining a direct backlight unit 2300 including a light-emitting device package according to one or more embodiments.

Referring to FIG. 12, the backlight unit 2300 according to the embodiment may include an optical sheet 2320 and light source modules 2310 arranged on a lower portion of the optical sheet 2320. The optical sheet 2320 may include a diffusion sheet 2321, a light collection sheet 2322, a protection sheet 2323, etc.

The light source module 2310 may include a circuit board 2311, a plurality of light sources 2312 mounted on the circuit board 2311, and a plurality of optical devices 2313 respectively disposed on the plurality of light sources 2312. The plurality of light sources 2312 may be any one of the light-emitting device packages 100, 100A, and 100B according to one or more embodiments described above.

The optical device 2313 may adjust a beam angle of light through refraction, and in particular, a light beam angle lens that spreads the light source 2312 over a wide region may be used. The light source 2312 to which the optical device 2313 is attached has a wider light distribution, and thus, the number of light sources 2312 per same area may be saved when a light source module is used for backlighting, flat lighting, etc.

FIG. 13 is a diagram for explaining a direct backlight unit 2400 including a light-emitting device package according to one or more embodiments.

Referring to FIG. 13, the backlight unit 2400 includes light sources 2405 mounted on a circuit board 2401 and one or more optical sheets 2406 disposed on the light sources 2405.

The light source 2405 may be a white light-emitting device including red phosphor. The light source 2405 may be a module mounted on the circuit board 2401. The light source 2405 may be any one of the light-emitting device packages 100, 100A, and 100B according to one or more embodiments described above.

The circuit board 2401 used in the embodiment may have a first flat portion 2401a corresponding to a main region, an inclined portion 2401b disposed around the first flat portion 2401a and at least partially bent, and a second flat portion 2401c disposed at a corner of the circuit board 2401 which is the outside of the inclined portion 2401b.

The light source 2405 may be arranged on the first flat portion 2401a at a first distance d1, and the one or more light sources 2405 may be arranged on the inclined portion 2401b at a second distance d2. The first distance d1 may be equal to the second distance d2. A width (or a length in a cross section) of the inclined portion 2401b may be less than a width of the first flat portion 2401a and longer than a width of the second flat portion 2401c. In addition, the at least one light source 2405 may be arranged in the second flat portion 2401c, as needed.

An inclination of the inclined portion 2401b may be appropriately adjusted within a range greater than about 0° and less than about 90° with respect to the first flat portion 2401a. The circuit board 2401 having such a structure may maintain uniform brightness even near an edge of the optical sheet 2406.

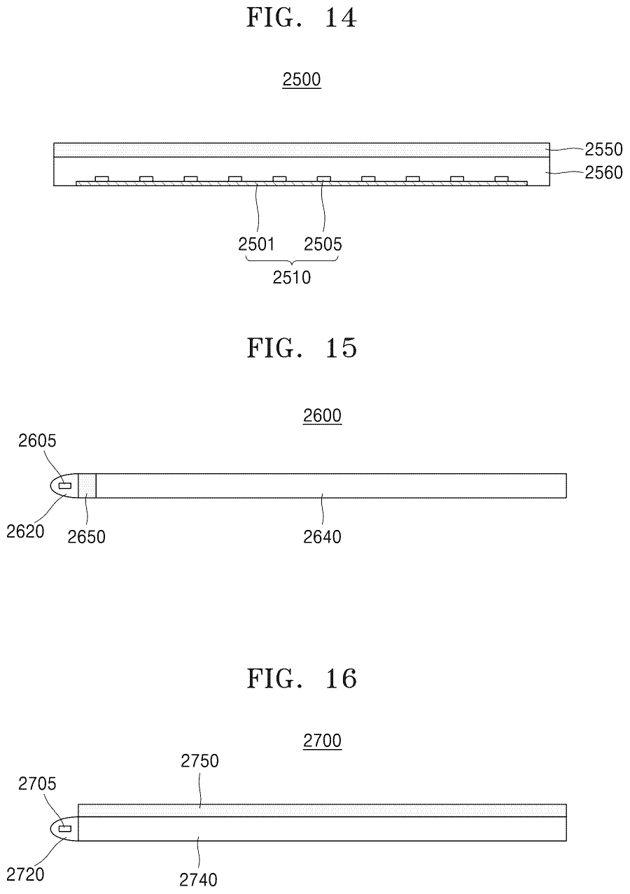

FIGS. 14 to 16 are diagrams for explaining backlight units 2500, 2600, and 2700 including light-emitting device packages according to one or more embodiments.

Referring to FIGS. 14 to 16, in the backlight units 2500, 2600, and 2700, wavelength conversion portions 2550, 2650, and 2750 may not be respectively disposed at light sources 2505, 2605, and 2705, and may be disposed in the backlight units 2500, 2600, and 2700 outside the light sources 2505, 2605, and 2705 to convert light. The light sources 2505, 2605, and 2705 may be any one of the light-emitting device packages 100, 100A, and 100B according to one or more embodiments described above.

The backlight unit 2500 of FIG. 14 is a direct backlight unit, and may include the wavelength conversion portion 2550, light source modules 2510 arranged on a lower portion of the wavelength conversion portion 2550, and a bottom case 2560 accommodating the light source modules 2510. In addition, the light source module 2510 may include a printed circuit board 2501 and a plurality of light sources 2505 mounted on an upper surface of the printed circuit board 2501.

In the backlight unit 2500, a wavelength conversion portion 2550 may be disposed on the top of the bottom case 2560. Accordingly, at least part of light emitted from the light source module 2510 may have its wavelength converted by the wavelength conversion portion 2550. The wavelength conversion portion 2550 may be applied as a separate film, but is not limited thereto.

The backlight units 2600 and 2700 of FIGS. 15 and 16 are edge backlight units, and may include the wavelength conversion portions 2650 and 2750, light guide plates 2640 and 2740, reflectors 2620 and 2720 disposed on one sides of the light guide plates 2640 and 2740, and the light sources 2605 and 2705. Light emitted from the light sources 2605 and 2705 may be guided into the light guide plates 2640 and 2740 by the reflectors 2620 and 2720.

In the backlight unit 2600 of FIG. 15, the wavelength conversion portion 2650 may be disposed between the light guide plate 2640 and the light source 2605. In the backlight unit 2700 of FIG. 16, the wavelength conversion portion 2750 may be disposed on a light emission surface of the light guide plate 2740.

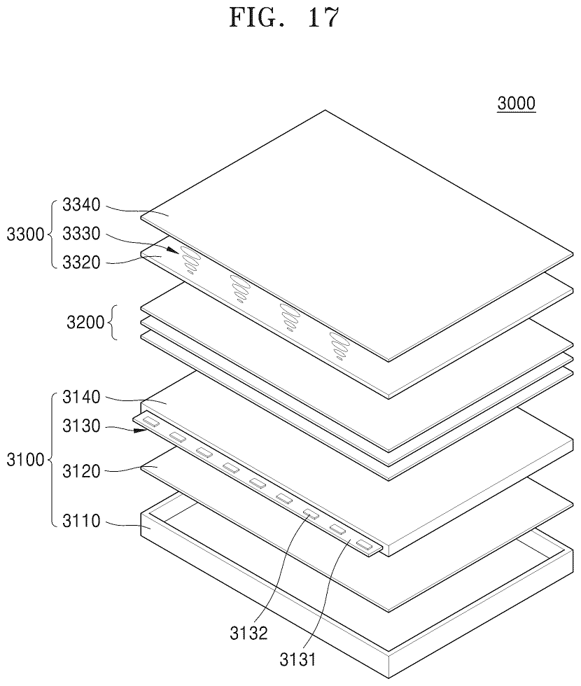

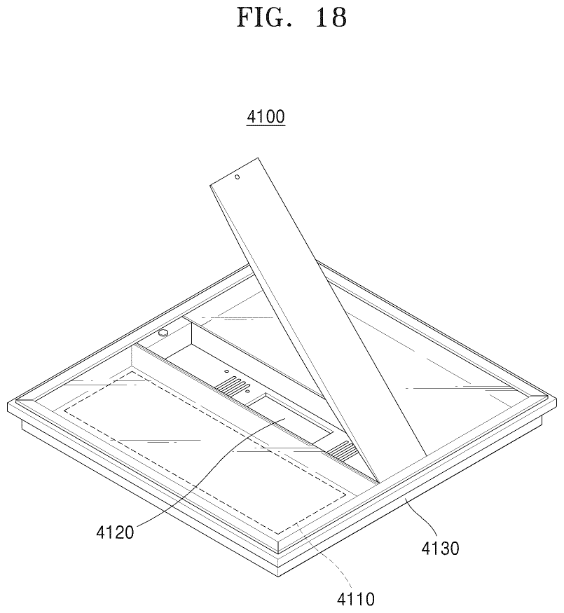

FIG. 17 is a schematic exploded perspective view of a display device 3000 including a light-emitting device package according to one or more embodiments.

Referring to FIG. 17, the display device 3000 may include a backlight unit 3100, an optical sheet 3200, and an image display panel 3300 such as a liquid crystal panel. The backlight unit 3100 may include a bottom case 3110, a reflector 3120, a light guide plate 3140, and a light source module 3130 provided on at least one side of the light guide plate 3140. The light source module 3130 may include a printed circuit board 3131 and a light source 3132.

In particular, the light source 3132 may be a side view type light-emitting device mounted on the side adjacent to a light emission surface. The light source 3132 may be any one of the light-emitting device packages 100, 100A, and 100B according to one or more embodiments described above.

The image display panel 3300 may display an image by using light emitted from the optical sheet 3200. The image display panel 3300 may include an array substrate 3320, a liquid crystal layer 3330, and a color filter substrate 3340. The array substrate 3320 may include pixel electrodes arranged in a matrix form, thin film transistors applying a driving voltage to the pixel electrodes, and signal lines for operating the thin film transistors.

The color filter substrate 3340 may include a transparent substrate, a color filter, and a common electrode. The color filter may include a filter through which light of a specific wavelength selectively passes in white light emitted from the backlight unit 3100. The liquid crystal layer 3330 may be rearranged by an electric field formed between the pixel electrode and the common electrode to adjust light transmittance. Light with the adjusted light transmittance may pass through the color filter of the color filter substrate 3340 to display an image. The image display panel 3300 may further include a driving circuit unit that processes an image signal.

FIG. 18 is a perspective view schematically showing a flat lighting device 4100 including a light-emitting device package according to one or more embodiments.

Referring to FIG. 18, the flat lighting device 4100 may include a light source module 4110, a power supply device 4120, and a housing 4130. The light source module 4110 may include a light-emitting device array as a light source, and the power supply device 4120 may include a light-emitting device driver. The light source module 4110 may be any one of the light-emitting device packages 100, 100A, and 100B according to one or more embodiments described above.

The light source module 4110 may include a light-emitting device array and may be formed to have an overall planar shape. The light-emitting device array may include a light-emitting device and a controller that stores driving information of the light-emitting device.

The power supply device 4120 may be configured to supply power to the light source module 4110. The housing 4130 may include an accommodating space to accommodate the light source module 4110 and the power supply device 4120 therein, and may be formed in a hexahedral shape open to one side surface, but is not limited thereto. The light source module 4110 may be disposed to emit light to the open one side surface of the housing 4130.

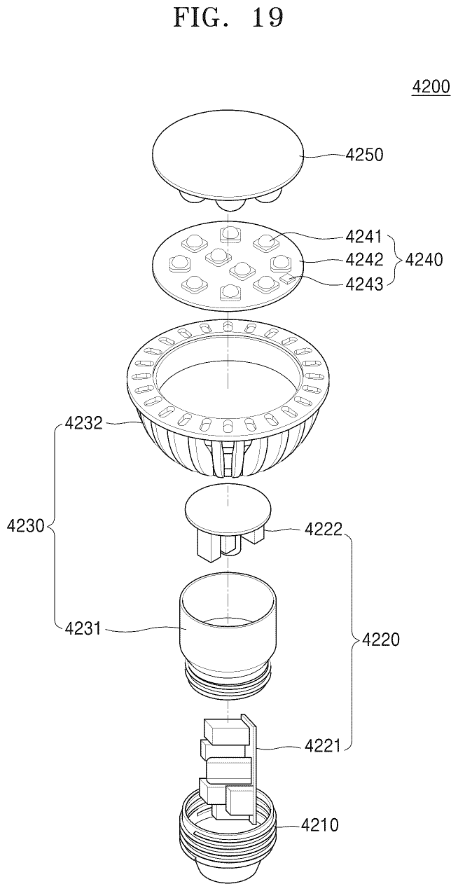

FIG. 19 is an exploded perspective view schematically showing a lighting device 4200 including light-emitting device packages 4241 according to one or more embodiments.

Referring to FIG. 19, the lighting device 4200 may include a socket 4210, a power supply portion 4220, a heat dissipation portion 4230, a light source module 4240, and an optical portion 4250. The light source module 4240 may include a light-emitting device array, and the power supply portion 4220 may include a light-emitting device driver.

The socket 4210 may be configured to replace the existing lighting device. Power supplied to the lighting device 4200 may be applied through the socket 4210. The power supply portion 4220 may be separate into a first power supply portion 4221 and a second power supply portion 4222 and assembled. The heat dissipation portion 4230 may include an internal heat dissipation portion 4231 and an external heat dissipation portion 4232, and the internal heat dissipation portion 4231 may be directly connected to the light source module 4240 and/or the power supply portion 4220 so that heat may be transferred to the external heat dissipation portion 4232.

The light source module 4240 may receive power from the power supply portion 4220 and emit light to the optical portion 4250. The light source module 4240 may include one or more light-emitting device packages 4241, a circuit board 4242, and a controller 4243, and the controller 4243 may store driving information of the light-emitting device packages 4241. The light-emitting device package 4241 may be any one of the light-emitting device packages 100, 100A, and 100B according to one or more embodiments described above.

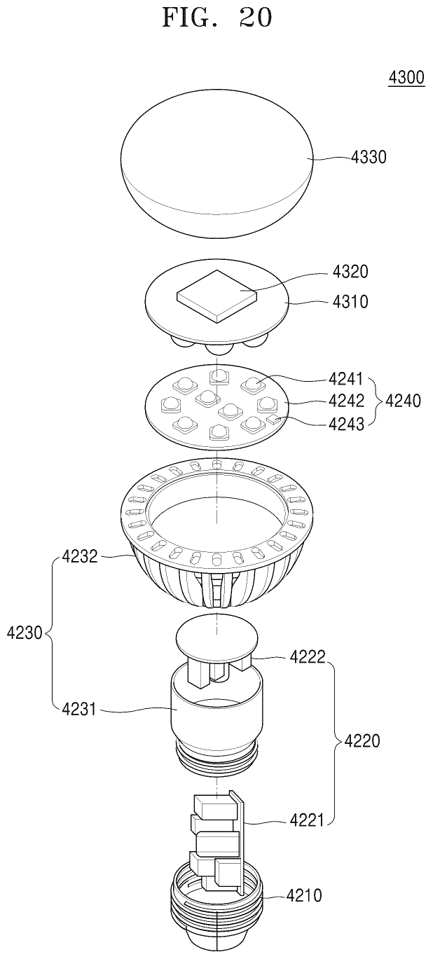

FIG. 20 is an exploded perspective view schematically showing a lighting device 4300 including a light-emitting device package according to one or more embodiments.

Referring to FIG. 20, unlike the lighting device 4200 shown in FIG. 19, the lighting device 4300 according to the embodiment may include a reflector 4310 and a communication module 4320 on an upper portion of the light source module 4240. The reflector 4310 may reduce glare by evenly spreading light from a light source to side surfaces and rear.

The communication module 4320 may be mounted on an upper portion of the reflector 4310, and home network communication may be implemented through the communication module 4320. For example, the communication module 4320 may be a wireless communication module using Bluetooth, WiFi, or LiFi, and may control lighting installed inside and outside the home, such as turning on/off the lighting device 4300, controlling brightness, etc. through a smartphone or a wireless controller.

In addition, the communication module 4320 may control an electronic product inside and outside the home, such as a TV, a refrigerator, an air conditioner, a door lock, etc., and an automobile system by using a Li-Fi communication module using a visible light wavelength of the lighting device 4300 installed inside and outside the home. The reflector 4310 and the communication module 4320 may be covered by a cover portion 4330.

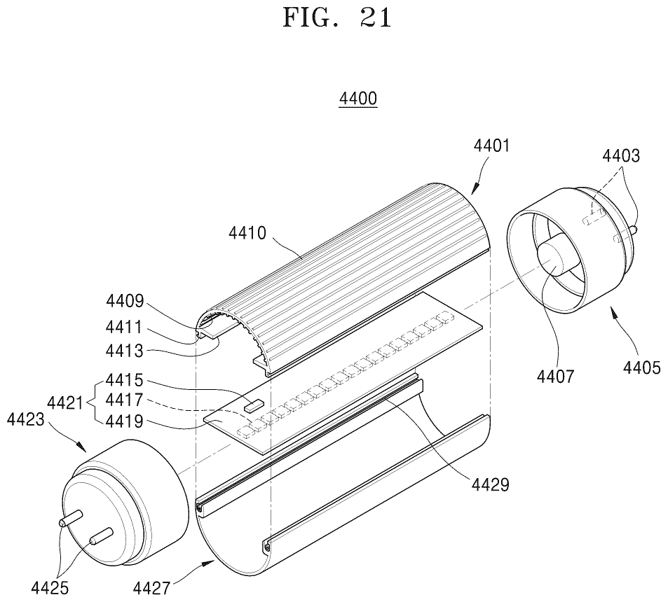

FIG. 21 is an exploded perspective view schematically showing a bar-type lighting device 4400 including a light-emitting device package according to one or more embodiments.

Referring to FIG. 21, the lighting device 4400 includes a heat dissipation member 4401, a cover 4427, a light source module 4421, a first socket 4405, and a second socket 4423.

A plurality of heat dissipation fins 4409 and 4410 may be formed in an uneven shape on an inner surface and/or an outer surface of the heat dissipation member 4401, and may be designed to have various shapes and distances.

A support 4413 in the form of a protrusion is formed inside the heat dissipation member 4401. The light source module 4421 may be fixed to the support 4413. Locking protrusions 4411 may be formed at both ends of the heat dissipation member 4401. Locking grooves 4429 are formed in the cover 4427, and the locking protrusions 4411 of the heat dissipation member 4401 may be coupled to the locking grooves 4429 in a hook coupling structure. Positions at which the locking grooves 4429 and the locking protrusions 4411 are formed may be switched.

The light source module 4421 may include a light-emitting device array. The light source module 4421 may include a printed circuit board 4419, a light source 4417, and a controller 4415. The controller 4415 may store driving information of the light source 4417. Circuit wirings for operating the light source 4417 are formed on the printed circuit board 4419. In addition, components for operating the light source 4417 may be included. The light source 4417 may be any one of the light-emitting device packages 100, 100A, and 100B according to one or more embodiments described above.

The first socket 4405 and the second socket 4423 are a pair of sockets and have a structure coupled to both ends of a cylindrical cover unit including the heat dissipation member 4401 and the cover 4427. For example, the first socket 4405 may include an electrode terminal 4403 and a power supply 4407, and a dummy terminal 4425 may be disposed in the second socket 4423. In addition, an optical sensor and/or a communication module may be embedded in either the first socket 4405 or the second socket 4423.

In some embodiments, an optical sensor and/or a communication module may be embedded in the first socket 4405 where the electrode terminal 4403 is disposed. In some embodiments, an optical sensor and/or a communication module may be embedded in the second socket 4423 where the dummy terminal 4425 is disposed.

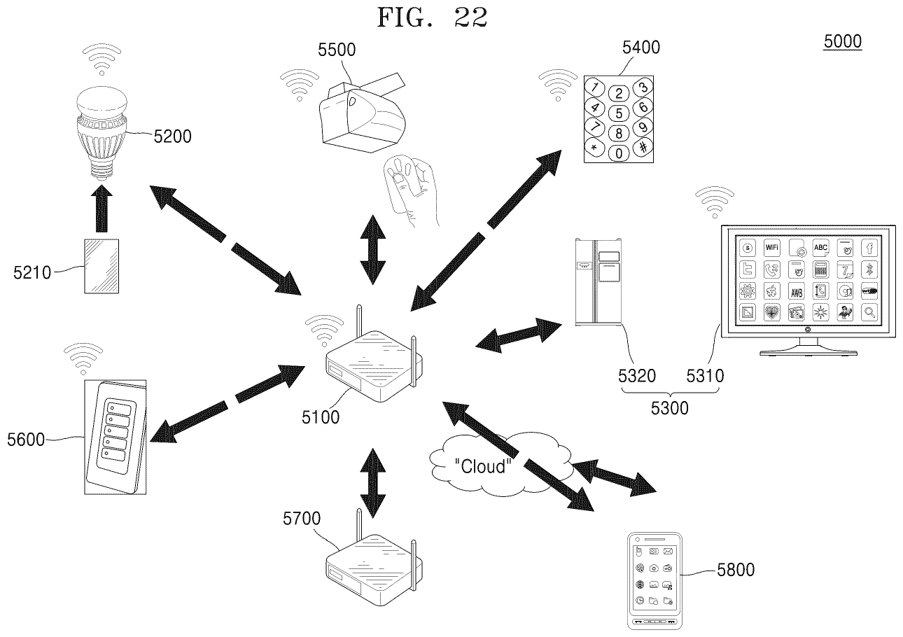

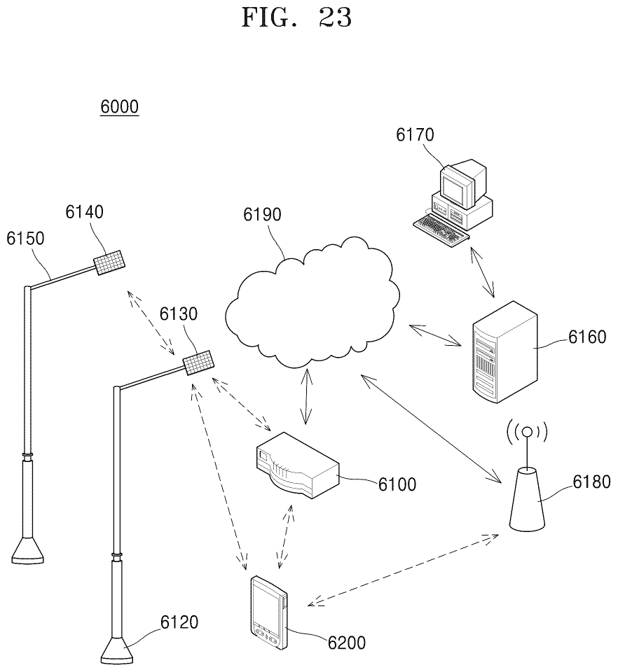

FIG. 22 is a schematic diagram illustrating a network system 5000 for indoor lighting control, the network system 5000 including a light-emitting device package according to one or more embodiments.

Referring to FIG. 22, the network system 5000 may be a complex smart lighting network system that combines lighting technology using a light-emitting device, Internet of Things (IoT) technology, and wireless communication technology.

The network system 5000 may be implemented using various lighting devices and wired and wireless communication devices, and may be implemented using a sensor, a controller, communication means, network control, and software for maintenance.

The network system 5000 may be applied to a closed space defined within a building, such as home or office, as well as an open space, such as a park and a street. The network system 5000 may be implemented based on an IoT environment to collect/process various kinds of information and provide the information to a user.

An LED lamp 5200 included in the network system 5000 may receive information about the surrounding environment from a gateway 5100 and control lighting of the LED lamp 5200 itself, as well as perform functions such as checking and controlling operating states of a plurality of devices 5300 to 5800 included in the IoT environment based on a function of visible light communication of the LED lamp 5200. The LED lamp 5200 may be any one of the light-emitting device packages 100, 100A, and 100B according to one or more embodiments described above.

The network system 5000 may include a gateway 5100 for processing data transmitted and received according to different communication protocols, the LED lamp 5200 connected to the gateway 5100 to enable communication and including an LED light-emitting device, and the plurality of devices 5300 to 5800 connected to the gateway 5100 to enable communication according to various wireless communication methods.

To implement the network system 5000 based on the IoT environment, the plurality of devices 5300 to 5800, including the LED lamp 5200, may include at least one communication module. In some embodiments, the LED lamp 5200 may be connected to the gateway 5100 to enable communication by a wireless communication protocol such as Bluetooth, Wi-Fi, or Li-Fi, and may have at least one lamp communication module 5210 to this end.

When the network system 5000 is applied to home, the plurality of devices 5300 to 5800 connected to the gateway 5100 to enable communication based on the IoT technology may include a home appliance 5300, a digital door lock 5400, a garage door lock 5500, a lighting switch 5600 installed on the wall, a router 5700 for wireless communication network relay, and a mobile device 5800 such as a smartphone, a tablet, and a laptop computer.

In the network system 5000, the LED lamp 5200 may check the operating states of the plurality of devices 5300 to 5800 by using a wireless communication network installed at home, or automatically adjust the illuminance of the LED lamp 5200 according to the surrounding environment and situation. In addition, the plurality of devices 5300 to 5800 may be controlled using Li-Fi communication using visible light emitted from the LED lamp 5200.

First, the LED lamp 5200 may automatically adjust the illuminance of the LED lamp 5200 based on surrounding environment information transmitted from the gateway 5100 through the lamp communication module 5210, or surrounding environment information collected from the sensor mounted on the LED lamp 5200. For example, the brightness of the LED lamp 5200 may be automatically adjusted according to a type of program being broadcast on a TV 5310 or brightness of a screen. To this end, the LED lamp 5200 may receive operation information of the TV 5310 from the lamp communication module 5210 connected to the gateway 5100. The lamp communication module 5210 may be integrated with the sensor and/or the controller included in the LED lamp 5200.

In addition, when a certain period of time elapses after the digital door lock 5400 is locked while no person is at home, all of the LED lamps 5200 which are turned on may be turned off to prevent electricity waste. Alternatively, when a security mode is set through the mobile device 5800 and the digital door lock 5400 is locked while no person is at home, the LED lamp 5200 may remain turned on.

The operation of the LED lamp 5200 may be controlled according to surrounding environment information collected through various sensors connected to the network system 5000. For example, when the network system 5000 is implemented within a building, lighting is turned on or off by combining lighting, a location sensor, and a communication module in the building and collecting location information of people in the building, or efficient use of facility management or idle space enables by providing the collected information in real time.

Meanwhile, the LED lamp 5200 may be combined with an image sensor, a storage device, and the lamp communication module 5210, and may be used as a device capable of maintaining building security or detecting and responding to an emergency situation. For example, when a smoke or temperature detection sensor is attached to the LED lamp 5200, damage may be minimized by quickly detecting whether a fire has occurred. In addition, by adjusting the brightness of lighting in consideration of the external weather or the amount of sunlight, energy may be saved and a comfortable lighting environment may be provided.

As described above, the network system 5000 may be applied to a closed space such as home, office, or building, as well as an open space such as a street and a park. When attempting to apply the network system 5000 to an open space without physical limitations, it may be relatively difficult to implement the network system 5000 due to distance limitations of wireless communication and communication interference due to various obstacles. The network system 5000 may be efficiently implemented in an open environment by mounting a sensor and a communication module to each lighting instrument and using each lighting instrument as information collection means and communication mediation means.

FIG. 23 is a schematic diagram illustrating a network system 6000 including a light-emitting device package according to one or more embodiments.

Referring to FIG. 23, one or more embodiments of the network system 6000 applied to an open space is shown. The network system 6000 may include a communication connection device 6100, a plurality of lighting instruments 6120 and 6150 installed at certain distances and connected to the communication connection device 6100 to enable communication, a server 6160, a computer 6170 managing the server 6160, a communication base station 6180, a communication network 6190 connecting communicable equipment, and a mobile device 6200.

The plurality of lighting instruments 6120 and 6150 installed in open outdoor spaces such as streets and parks may respectively include smart engines 6130 and 6140. The smart engines 6130 and 6140 each may include a light-emitting device emitting light, a driver driving the light-emitting device, a sensor collecting information of a surrounding environment, and a communication module. The light-emitting device included in the smart engines 6130 and 6140 may be any one of the light-emitting device packages 100, 100A, and 100B according to one or more embodiments described above.

Through the communication module, the smart engines 6130 and 6140 may communicate with other surrounding equipment according to a communication protocol.

In some embodiments, one smart engine 6130 may be connected to communicate with another smart engine 6140. WiFi mesh may be applied to communication between the smart engines 6130 and 6140. The at least one smart engine 6130 may be connected to the communication connection device 6100 connected to the communication network 6190 through wired/wireless communication. To increase communication efficiency, the several smart engines 6130 and 6140 may be grouped into one group and connected to one communication connection device 6100.

The communication connection device 6100 is an access point capable of wired/wireless communication and may mediate communication between the communication network 6190 and other equipment. The communication connection device 6100 may be connected to the communication network 6190 by using at least one of wired and wireless methods, and, for example, may be mechanically stored inside one of the lighting instruments 6120 and 6150.

The communication connection device 6100 may be connected to the mobile device 6200 through a communication protocol. A user of the mobile device 6200 may receive surrounding environment information collected by the plurality of smart engines 6130 and 6140 through the communication connection device 6100 connected to the smart engine 6130 of the surrounding lighting instrument 6120. The surrounding environment information may include surrounding traffic information, weather information, etc. The mobile device 6200 may be connected to the communication network 6190 by using a wireless cellular communication method through the communication base station 6180.

Meanwhile, the server 6160 connected to the communication network 6190 may receive the information collected by the smart engines 6130 and 6140 respectively mounted on the lighting instrument 6120 and 6150, and simultaneously monitor operating states of the lighting instrument 6120 and 6150. In order to manage each of the lighting instrument 6120 and 6150 based on monitoring results of the operating states of the lighting instrument 6120 and 6150, the server 6160 may be connected to a computer 6170 that provides a management system. The computer 6170 may execute software capable of monitoring and managing the operating states of the lighting instrument 6120 and 6150, particularly the smart engines 6130 and 6140.

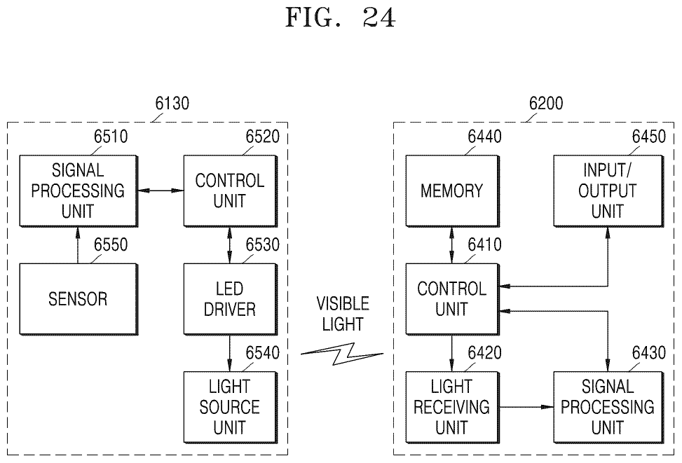

FIG. 24 is a block diagram for explaining a communication operation between the smart engine 6130 of a lighting instrument including a light-emitting device package and the mobile device 6200 according to one or more embodiments.

FIG. 24 shows the block diagram for explaining the communication operation between the smart engine 6130 of the lighting instrument 6120 (see FIG. 23) and the mobile device 6200 through wireless communication.

A variety of communication methods may be applied to transmit information collected by the smart engine 6130 to the user's mobile device 6200.

The information collected by the smart engine 6130 may be transmitted to the mobile device 6200 through the communication connection device 6100 (see FIG. 23) connected to the smart engine 6130, or the smart engine 6130 and the mobile device 6200 may be directly connected to communicate with each other. The smart engine 6130 and the mobile device 6200 may communicate directly with each other via Li-Fi.

The smart engine 6130 may include a signal processing unit 6510, a control unit 6520, an LED driver 6530, a light source unit 6540, and a sensor 6550. The mobile device 6200 connected to the smart engine 6130 by visible light wireless communication may include a control unit 6410, a light receiving unit 6420, a signal processing unit 6430, a memory 6440, and an input/output unit 6450.

The signal processing unit 6510 of the smart engine 6130 may process data to be transmitted and received through visible light wireless communication. In some embodiments, the signal processing unit 6510 may process information collected by the sensor 6550 into data and transmit the data to the control unit 6520. The control unit 6520 may control operations of the signal processing unit 6510 and the LED driver 6530, and in particular, may control the operation of the LED driver 6530 based on the data transmitted by the signal processing unit 6510. The LED driver 6530 may transmit data to the mobile device 6200 by causing the light source unit 6540 to emit light according to a control signal transmitted by the control unit 6520.

The mobile device 6200 may include the control unit 6410, the light receiving unit 6420 recognizing visible light including data, the signal processing unit 6430, the memory 6440 storing data, and the input/output unit 6450 including a display, a touch screen, or an audio output unit.

The light receiving unit 6420 may detect visible light and convert the visible light into an electrical signal, and the signal processing unit 6430 may decode data included in the electrical signal converted by the light receiving unit 6420. The control unit 6410 may store the data decoded by the signal processing unit 6430 in the memory 6440 or output the data to be recognized by the user through the input/output unit 6450.

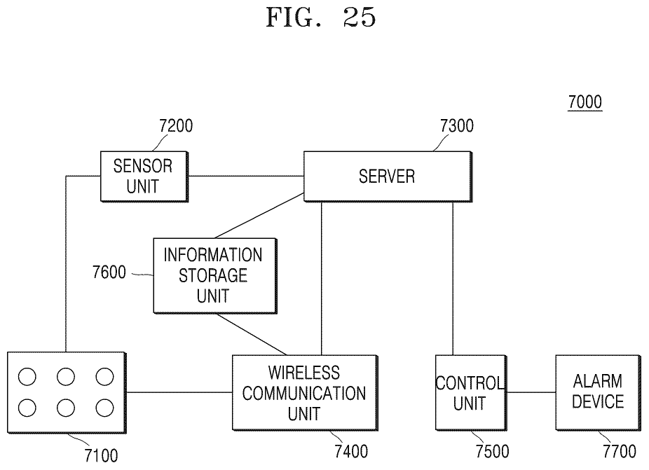

FIG. 25 is a conceptual diagram schematically showing a smart lighting system 7000 including a light-emitting device package according to one or more embodiments.

Referring to FIG. 25, the smart lighting system 7000 may include a lighting unit 7100, a sensor unit 7200, a server 7300, a wireless communication unit 7400, a control unit 7500, and an information storage unit 7600.

The lighting unit 7100 includes at least one lighting device in a building, and there is no limitation on the type of lighting device. For example, the lighting unit 7100 may include basic lighting, mood lighting, stand lighting, or decorative lighting in a living room, a room, balcony, a kitchen, a bathroom, a staircase, or an entrance. The lighting device may be any one of the light-emitting device packages 100, 100A, and 100B according to one or more embodiments described above.

The sensor unit 7200 is a portion that detects lighting conditions related to the turning on/off of each lighting device and the intensity of lighting, outputs a corresponding signal, and transmits the signal to the server 7300. The sensor unit 7200 may be provided in a building where a lighting device is installed, and the at least one sensor unit 7200 may be placed at a location where lighting states of all lighting devices controlled by the smart lighting system 7000 are detected, and may be provided together with each lighting device.

Information of the lighting states may be transmitted to the server 7300 in real time, or may be transmitted separately in certain time units. The server 7300 may be installed inside and/or outside the building, and receive the signal from the sensor unit 7200 to collect information about a lighting state of the turning on/off of the lighting unit 7100 in the building, group the collected information, define a lighting pattern based on the grouped information, and provide information about the defined pattern to the wireless communication unit 7400. In addition, the server 7300 may serve as a medium transmitting commands received from the wireless communication unit 7400 to the control unit 7500.

One server 7300 is shown but two or more servers may be provided as needed. The information storage unit 7600 may be a storage device accessible through a network.

The wireless communication unit 7400 is a portion that selects one of a plurality of lighting patterns provided from the server 7300 and/or the information storage unit 7600 and transmits a run or stop command signal to the server 7300 and may apply various portable wireless communication devices such as a smartphone, a tablet PC, a PDA, a laptop, etc. that may be carried by a user using the smart lighting system 7000.

As described above, the wireless communication unit 7400 may exchange necessary commands or information signals with the server 7300 and/or the information storage unit 7600, and the server 7300 may serve as a medium between the wireless communication unit 7400, the sensor unit 7200, and the control unit 7500, and thus, the smart lighting system 7000 may be driven.

In addition, the smart lighting system 7000 may place an alarm device 7700 within a building. The alarm device 7700 is used to warn when there is an intruder in the building. Specifically, when a situation that an intruder occurs in the building and deviates from a set lighting pattern occurs, the sensor unit 7200 may detect the situation and transmit a warning signal to the server 7300, and the server 7300 may notify the situation to the wireless communication unit 7400, and simultaneously transmit the warning signal to the control unit 7500 to operate the alarm device 7700 in the building.

While the disclosure has been particularly shown and described with reference to embodiments thereof, it will be understood that various changes in form and details may be made therein without departing from the spirit and scope of the following claims.

What is claimed is:

1. A light-emitting device package comprising:
a body portion comprising a first electrode and a second electrode;
a semiconductor light-emitting device on the body portion and configured to emit blue light; and
a wavelength conversion portion covering the semiconductor light-emitting device,
wherein the wavelength conversion portion comprises a transparent encapsulant and a plurality of wavelength conversion materials inside the transparent encapsulant,
wherein the plurality of wavelength conversion materials comprise a green wavelength conversion material, a first red wavelength conversion material, and a second red wavelength conversion material,
wherein the first red wavelength conversion material comprises a Mn⁴⁺ active phosphor,
wherein the second red wavelength conversion material comprises a Eu²⁺ active phosphor comprising oxygen of more than about 0 wt % and about 2.4 wt % or less, and
wherein a weight ratio of the second red wavelength conversion material among the plurality of wavelength conversion materials is about 1 wt % to about 6 wt %.

2. The light-emitting device package of claim 1,
wherein the first red wavelength conversion material comprises a K₂SiF₆:Mn⁴⁺ phosphor, and
wherein a weight ratio of the first red wavelength conversion material among the plurality of wavelength conversion materials is about 32 wt % to about 56 wt %.

3. The light-emitting device package of claim 1,
wherein the second red wavelength conversion material comprises a (Sr,Ca)AlSi(ON)₃:Eu²⁺ phosphor, and
wherein a weight ratio of the second red wavelength conversion material to a total weight ratio of the first red wavelength conversion material and the second red wavelength conversion material is about 5 wt % to about 10 wt %.

4. The light-emitting device package of claim 3, wherein through the second red wavelength conversion material, the light-emitting device package is configured to emit red light having a peak wavelength of about 595 nm to about 615 nm and a full width at half maximum (FWHM) of 78 nm or less.

5. The light-emitting device package of claim 1, wherein the green wavelength conversion material comprises a Ce³⁺ active phosphor.

6. The light-emitting device package of claim 1,
wherein the green wavelength conversion material comprises a Y₃(Al,Ga)₅O₁₂:Ce³⁺ phosphor, and
wherein a weight ratio of the green wavelength conversion material among the plurality of wavelength conversion materials is about 38 wt % to about 64 wt %.

7. The light-emitting device package of claim 1, wherein the transparent encapsulant comprises silicone having a refractive index of about 1.41 to about 1.54.

8. The light-emitting device package of claim 1, wherein the semiconductor light-emitting device is configured to emit blue light having a peak wavelength of about 447 nm to about 457 nm.

9. The light-emitting device package of claim 1,
wherein the transparent encapsulant has a first section closest to the body portion and a second section furthest from the body portion, and
wherein the plurality of wavelength conversion materials are dispersed in the first section and the second section of the transparent encapsulant.

10. The light-emitting device package of claim 1,
wherein the transparent encapsulant has a first section closest to the body portion and a second section furthest from the body portion, and
wherein the plurality of wavelength conversion materials are dispersed and disposed only in the first section of the transparent encapsulant.

11. A light-emitting device package comprising:
a plurality of wavelength conversion materials configured to emit white light with a color rendering index (CRI) of 90 or more and an R9 value of 50 or more from blue light having a peak wavelength of about 447 nm to about 457 nm emitted from a semiconductor light-emitting device,
wherein the plurality of wavelength conversion materials comprise:
a Y₃(Al,Ga)₅O₁₂:Ce³⁺ phosphor as a green wavelength conversion material;
a K₂SiF₆:Mn⁴⁺ phosphor as a first red wavelength conversion material; and
a (Sr,Ca)AlSi(ON)₃:Eu²⁺ phosphor as a second red wavelength conversion material, and
wherein a weight ratio of the second red wavelength conversion material among the plurality of wavelength conversion materials is about 1 wt % to about 6 wt %.

12. The light-emitting device package of claim 11, wherein the second red wavelength conversion material comprises oxygen of more than about 0 wt % and about 2.4 wt % or less.

13. The light-emitting device package of claim 11, wherein a weight ratio of the second red wavelength conversion material to a total weight ratio of the first red wavelength conversion material and the second red wavelength conversion material is about 5 wt % to about 10 wt %.

14. The light-emitting device package of claim 11, wherein through the second red wavelength conversion material, the light-emitting device package is configured to emit red light having a peak wavelength of about 595 nm to about 615 nm and a full width at half maximum (FWHM) of 78 nm or less.

15. The light-emitting device package of claim 11, wherein a weight ratio of the first red wavelength conversion material among the plurality of wavelength conversion materials is about 32 wt % to about 56 wt %.

16. A light-emitting device package comprising:
a plurality of wavelength conversion materials configured to emit white light with a color rendering index (CRI) of 90 or more and an R9 value of 50 or more from blue light having a peak wavelength of about 447 nm to about 457 nm emitted from a semiconductor light-emitting device,
wherein the plurality of wavelength conversion materials comprise:
a Y₃(Al,Ga)₅O₁₂:Ce³⁺ phosphor as a green wavelength conversion material;
a K₂SiF₆:Mn⁴⁺ phosphor as a first red wavelength conversion material; and
a (Sr,Ca)AlSi(ON)₃:Eu²⁺ phosphor comprising oxygen of more than about 0 wt % and about 2.4 wt % or less, as a second red wavelength conversion material.

17. The light-emitting device package of claim 16, wherein a weight ratio of the first red wavelength conversion material among the plurality of wavelength conversion materials is about 32 wt % to about 56 wt %.

18. The light-emitting device package of claim 16, wherein a weight ratio of the second red wavelength conversion material among the plurality of wavelength conversion materials is about 1 wt % to about 6 wt %.

19. The light-emitting device package of claim 16, wherein a weight ratio of the green wavelength conversion material among the plurality of wavelength conversion materials is about 38 wt % to about 64 wt %.

20. The light-emitting device package of claim 16, wherein through the second red wavelength conversion material, the light-emitting device package is configured to emit red light having a peak wavelength of about 595 nm to about 615 nm and a full width at half maximum (FWHM) of 78 nm or less.
